(19) United States
(12) Patent Application Publication
(10) Pub. No.: US 2010/0127338 A1
(43) Pub. Date: May 27, 2010

(54) SEMICONDUCTOR DEVICE AND METHOD FOR MANUFACTURING THE SAME

(76) Inventor: Do-Hun Kim, Seosan-Si (KR)

Correspondence Address: SHERR & VAUGHN, PLLC, 620 HERNDON PARKWAY, SUITE 320, HERNDON, VA, 20170, US

(21) Appl. No.: 12/624,737

(22) Filed: Nov. 24, 2009

(30) Foreign Application Priority Data
Nov. 26, 2008 (KR) 10-2008-0117873

(51) Int. Cl. H01L 29/78; H01L 21/336

(52) U.S. Cl. 257/408; 438/306; 257/E29.266; 257/E21.437

(57) ABSTRACT

A semiconductor device may include a semiconductor substrate, a salicide, a gate electrode, and an insulating layer. The semiconductor substrate has a lightly doped drain (LDD) region formed therein. The salicide is formed on the LDD region. The gate electrode is formed on the semiconductor substrate. The gate electrode has a stacked structure of a gate oxide and a metal layer. The insulating layer is formed on the semiconductor substrate and at a side of the gate electrode.

The present application claims priority under 35 U.S.C.119 to Korean Patent Application No. 10-2008-0117873 (filed on Nov. 26, 2008), which is hereby incorporated by reference in its entirety.

### BACKGROUND

In a semiconductor integrated circuit, a unit transistor needs to be manufactured in a miniaturized size. In the development of semiconductors, as the sizes of transistors progressively decreases, increases in gate resistance pose an obstacle to progress. Accordingly, a method capable of lowering a gate resistance of a transistor is required for higher scale integration of semiconductor devices.

### SUMMARY

Embodiments relate to a semiconductor device, and a method for manufacturing the same, which can reduce gate resistance in a semiconductor device. In embodiments, a semiconductor device may include: a semiconductor substrate with a lightly doped drain region, a salicide over the lightly doped drain region, a gate electrode over the semiconductor substrate, the gate electrode having a stacked structure including at least a gate oxide and a metal layer, and an insulating layer on the semiconductor substrate and at a side of the gate electrode. The gate oxide may be formed over an upper part of the semiconductor substrate and over a sidewall of the insulating layer.

A method of manufacturing the semiconductor device may include forming an lightly doped drain region in a semiconductor substrate, the semiconductor substrate having a device isolation layer; forming an oxide on the semiconductor substrate and etching the oxide to expose a portion of the semiconductor substrate in which the lightly doped drain region is formed; forming a salicide on the lightly doped drain region; removing the oxide; forming an insulating layer on the semiconductor substrate and etching the insulating layer to expose a portion of the semiconductor substrate; sequentially stacking a gate oxide and a metal layer on the exposed portion of the semiconductor substrate and the insulating layer; and forming a gate electrode by planarizing the metal layer and the gate oxide to expose a portion of the insulating layer.

### DRAWINGS

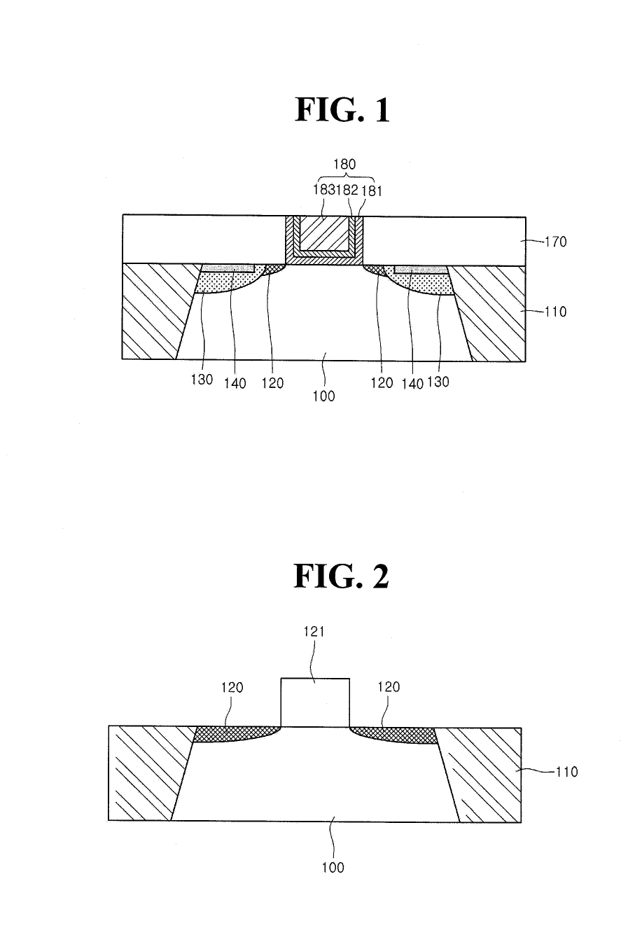

Example FIG. 1 is a cross-sectional view illustrating a configuration of a semiconductor device according to embodiments.

Example FIGS. 2 through 8 are cross-sectional views illustrating a method for manufacturing a semiconductor device according to embodiments.

### DESCRIPTION

Example FIG. 1 is a cross-sectional view illustrating a configuration of a semiconductor device according to embodiments. Referring to example FIG. 1, a semiconductor device may include an active region defined by a device isolation layer 110. Lightly doped drain (LDD) regions 120 and 130 may be formed at both sides of a gate electrode 180 in a semiconductor substrate 100.

The LDD region may includes a shallow LDD region (first LDD region) 120 and a deep LDD region (second LDD region) 130. A salicide 140 may be formed over the second LDD region 130. The salicide 140 may be formed through a sintering process after a metal for salicide such as Co, Ti, Ni, W, Pt, Hf, and Pd is deposited over the semiconductor substrate in which the second LDD region 130 is formed. But, embodiments are not limited to the metals for salicide.

In particular, unlike the related art, the salicide 140 may not be formed over the polysilicon constituting a gate electrode. In other words, the salicide 140 may not be formed over the gate electrode 180.

The gate electrode 180 may be interposed in an insulating layer 170 formed over the semiconductor substrate 100. The gate electrode includes a gate oxide 181, a barrier metal layer or a Cu-seed layer 182, and a Cu-metal layer 183 that are formed in an opening of the insulating layer 170. The gate oxide 181 may include a region formed over the semiconductor substrate 100 and another region extending in a vertical direction to the semiconductor substrate 100. The Cu-metal layer 183 may be formed over the bottom and sidewall of the gate oxide 181.

As the gate electrode constituting a transistor may be formed of Cu, the gate resistance can be reduced. The barrier metal layer 182 may be formed under the undersurface and the sidewall of the Cu-metal layer 183, and the gate oxide 181 may be formed under the undersurface and the sidewall of the barrier metal layer 182.

In other words, the gate electrode 180 may be formed in a hole of the insulating layer 170. The barrier metal layer 182 may be formed over the bottom and the inner side of the gate oxide 181, and the Cu-metal layer 183 may be formed over the bottom and the inner side of the barrier metal layer 182.

That is, the gate electrode 180 may have a structure in which the gate oxide 181, the barrier metal layer 182, and the Cu-metal layer 183 may be sequentially stacked, and the barrier metal layer 182 may be interposed between the gate oxide 181 and the Cu-metal layer 183. The gate electrode may include the Cu-metal layer 183 to reduce the gate resistance, and may have a structure in which a Cu-seed layer for forming the Cu-metal layer is formed over the barrier metal layer 182. The semiconductor device according to embodiments may have an advantage in that a fine semiconductor device can be formed due to a low gate resistance of a transistor by forming a low resistance gate electrode using Cu.

Hereinafter, a method for manufacturing the semiconductor device described above will be described in detain with reference to example FIGS. 2 through 8. Example FIGS. 2 through 8 are cross-sectional views illustrating a method for manufacturing a semiconductor device according to embodiments.

First, referring to example FIG. 2, a device isolation layer 110 may be formed to define an active region in a semiconductor substrate 100. A first photoresist pattern 121 may be formed to form a first LDD region 120 in the semiconductor substrate 100. Ions may be implanted into the semiconductor substrate 100, using the first photoresist pattern 121 as an ion implantation mask, to form the first LDD region 120 as described in example FIG. 2. Hereinafter, since the types of impurities and the ion implantation process for forming the LDD region may be varied with embodiments, detailed description thereof will be omitted. The first LDD regions 120 may be disposed at a certain interval.

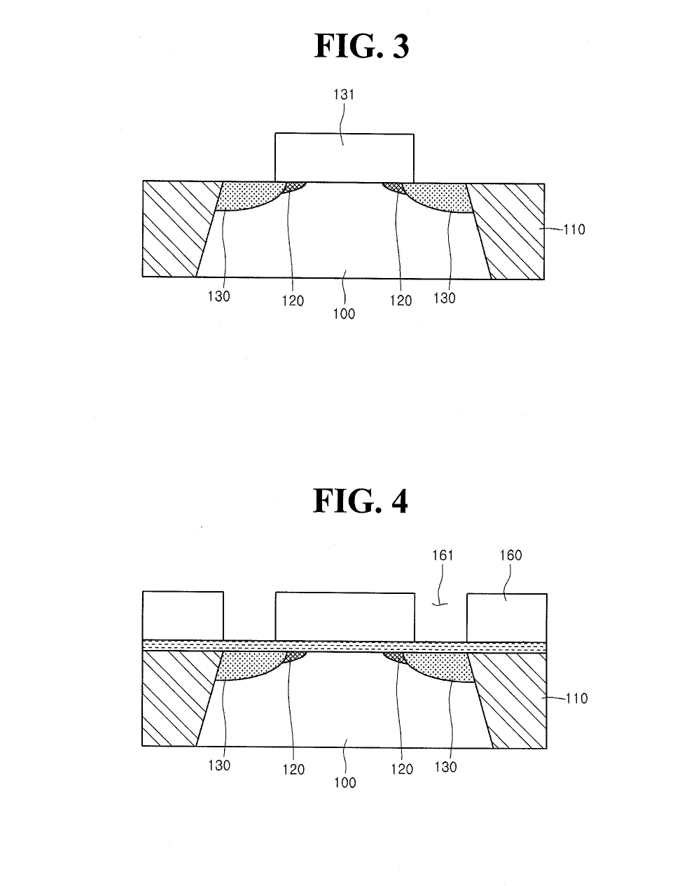

Next, referring to example FIG. 3, after the first LDD region 120 is formed in the semiconductor substrate 100, the first photoresist pattern 121 may be removed, and a process for forming a second LDD region 130 in the semiconductor substrate 100 may be performed. That is, a second photoresist pattern 131 may be formed to form the second LDD region 130 in the semiconductor substrate 100. Ions may be implanted into the semiconductor substrate 100 using the second photoresist pattern 131 as an ion implantation mask to form the second LDD region 130. Thus, the LDD regions 120 and 130 may be formed in the semiconductor substrate 100.

The first and second LDD region 120 and 130 are named a shallow source/drain region and a deep source/drain region, respectively, but may be variously defined according to the amount of implantation impurities and the implantation energy. After the second LDD region 130 is formed in the semiconductor substrate 100, the second photoresist pattern 131 may be removed.

Next, referring to example FIG. 4, an oxide 150 having a predetermined thickness may be deposited over the semiconductor substrate 100 in which the LDD regions 120 and 130 are formed. A third photoresist pattern 160 for forming a salicide may be formed over the oxide 150. Here, the third photoresist pattern may be patterned to form a salicide over the LDD regions 120 and 130. For reference, since a gate electrode such as related-art polysilicon is not yet formed, the salicide according to embodiments may be formed over the LDD region. That is, portions of the oxide 150 that are exposed by openings 161 of the third photoresist pattern 160 correspond to the LDD regions 120 and 130.

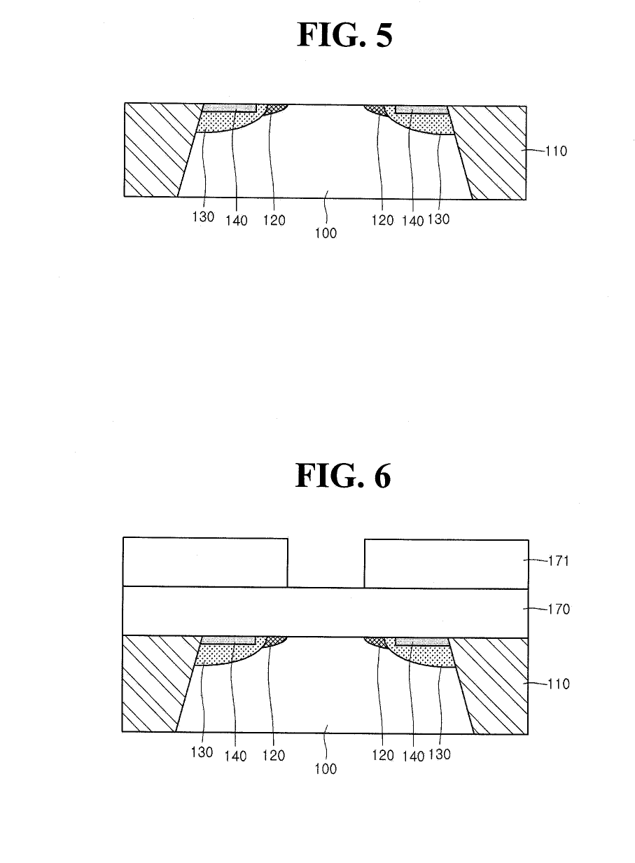

Next, referring to example FIG. 5, the oxide 150 may be etched using the third photoresist pattern 160 as an etch mask to expose a portion of the semiconductor substrate 100. After a salicide metal is formed over the semiconductor substrate 100 exposed by the etching process, a salicide 140 is formed over the LDD region through a sintering process. As described above, the salicide 140 may be formed over the LDD region through a sintering process after a metal for salicide such as Co, Ti, Ni, W, Pt, Hf, and Pd is deposited over the semiconductor substrate 100 in which the LDD region is already formed.

Then, an ashing process or a recess process may be performed to remove the third photoresist pattern 160. An etching process may be performed to remove the oxide 150 formed over the semiconductor substrate 100. After the etching process for removing the oxide 150, a planarization process may be performed for a subsequent process. The semiconductor substrate 100 in which the salicide 140 is formed by the above method has the structure as shown in example FIG. 5.

Next, referring to example FIG. 6, an insulating layer 170 may be deposited over the semiconductor substrate 100. A fourth photoresist pattern 171 may be formed over the insulating layer 170 to form a gate electrode. The insulating layer 170 may be formed of the same material as the oxide used to form the salicide 140. Both of the insulating layer 170 and the oxide may be formed of Tetra-Ethyl-Ortho-Silicate (TEOS). But, the insulating layer 170 may be formed of various insulating materials to perform interlayer insulation.

The fourth photoresist pattern 171 may be patterned to expose the insulating layer 170 of a region corresponding to a position where the gate electrode is formed. After the fourth photoresist pattern 171 is formed over the insulating layer 170, a Reactive Ion Etching (RIE) process may be performed on the entire surface of the semiconductor substrate 100 to remove by-products that may exist on the semiconductor substrate 100. After the RIE process following the formation of the fourth photoresist pattern, an etching process may be performed using the fourth photoresist pattern 171 as an etch mask to remove a portion of the insulating layer 170.

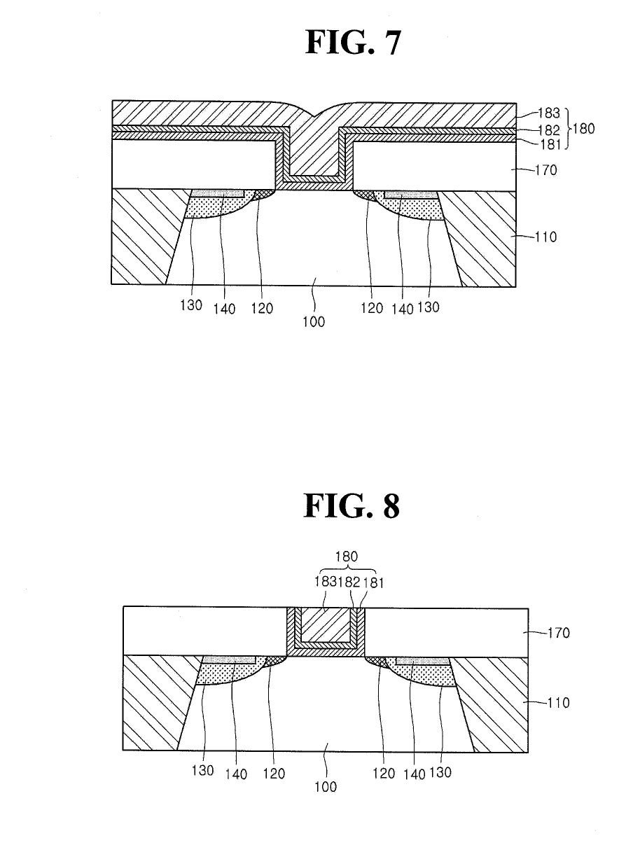

Next, referring to example FIG. 7, a portion of the insulating layer 170 of a region where a gate electrode is to be formed may be etched to expose a portion of the semiconductor substrate 100 corresponding to the region where the gate electrode is to be formed. Then, a gate oxide 181, a barrier metal layer 182, and a Cu-metal layer 183 are sequentially formed over the exposed portion of the semiconductor substrate 100 and the insulating layer 170.

That is, the gate oxide 181 may be deposited to have a predetermined thickness in an etched hole of the insulating layer 170. Then, the barrier metal layer 182 may be deposited with a predetermined thickness over the gate oxide 181. Thereafter, the Cu-metal layer 183 may be deposited by performing a Cu Electrochemical Plating (ECP) process after further forming a Cu-seed layer over the barrier metal layer 182. Through these processes, the structure, in which the gate oxide 181, the barrier metal layer 182, and the Cu-metal layer 183 are sequentially stacked, is formed as shown in example FIG. 7.

Next, referring to example FIG. 8, a planarization process may be performed on the Cu-metal layer 183 formed over the insulating layer 170 to remove portions of the Cu-metal layer 183, the barrier metal layer 182, and the gate oxide 181. That is, the planarization process may be performed on the Cu-metal layer 183, the barrier metal layer 182, and the gate oxide 181 to expose the upper surface of the insulating layer 170.

In regard to the gate electrode 180 according to embodiments, the insulating layer 170 has an opening where the gate electrode is to be formed, and the gate oxide 181 may be formed in the opening. The gate oxide 181 may be formed in a bent shape extending from the upper surface of the semiconductor substrate 100 exposed by the opening of the insulating layer 170 to the sidewall of the insulating layer 170.

In the semiconductor device and the method for manufacturing the same as described above, the magnitude of the gate resistance can be significantly reduced by forming a gate electrode using Cu. Thus, greater miniaturization of a semiconductor device can be also achieved. In addition, a bias application to a gate electrode can be further facilitated by forming the gate electrode using Cu. Furthermore, since a salicide need not be formed over a gate electrode, the manufacturing process can be simplified.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a semiconductor substrate with a lightly doped drain region;
a salicide over the lightly doped drain region;
a gate electrode over the semiconductor substrate, the gate electrode having a stacked structure including at least a gate oxide and a metal layer; and
an insulating layer on the semiconductor substrate and at a side of the gate electrode,
wherein the gate oxide is formed over an upper part of the semiconductor substrate and over a sidewall of the insulating layer.

2. The apparatus of claim 1, wherein the metal layer of the gate electrode comprises a Cu-metal layer.

3. The apparatus of claim 1, wherein the gate oxide and the metal layer have a barrier metal layer interposed therebetween.

4. The apparatus of claim 3, wherein the metal layer includes a seed layer adjacent the barrier metal layer.

5. The apparatus of claim 1, wherein the gate oxide extends to both sides of the metal layer.

6. The apparatus of claim 1, wherein the lightly doped drain region includes a shallow lightly doped drain region and a deep lightly doped drain region.

7. The apparatus of claim 6, wherein the salicide is formed over the deep lightly doped drain region.

8. An apparatus comprising:
a semiconductor substrate with a device isolation layer and an lightly doped drain region;
an insulating layer on the semiconductor device, the insulating layer defining an opening exposing a portion of an upper surface of the semiconductor substrate;
a gate oxide film in the opening of the insulating layer, the gate oxide film covering the exposed portion of the upper surface of the semiconductor substrate, and covering at least a sidewall of the insulating layer; and
a metal layer disposed on an inner side of the gate oxide film.

9. The apparatus of claim 8, wherein the metal layer is a Cu-metal layer.

10. The apparatus of claim 9, wherein the gate oxide film and the Cu-metal layer have a barrier metal layer and a Cu-seed layer sequentially stacked therebetween.

11. The apparatus of claim 8, wherein the lightly doped drain region includes a shallow lightly doped drain region and a deep lightly doped drain region.

12. The apparatus of claim 11, wherein the salicide is formed over the deep lightly doped drain region.

13. A method comprising:
forming an lightly doped drain region in a semiconductor substrate, the semiconductor substrate having a device isolation layer;
forming an oxide on the semiconductor substrate and etching the oxide to expose a portion of the semiconductor substrate in which the lightly doped drain region is formed;
forming a salicide on the lightly doped drain region;
removing the oxide;
forming an insulating layer on the semiconductor substrate and etching the insulating layer to expose a portion of the semiconductor substrate;
sequentially stacking a gate oxide and a metal layer on the exposed portion of the semiconductor substrate and the insulating layer; and
forming a gate electrode by planarizing the metal layer and the gate oxide to expose a portion of the insulating layer.

14. The method of claim 13, wherein the sequential stacking of the gate oxide and the metal layer includes:
forming the gate oxide on the exposed portion of the semiconductor substrate and the insulating layer;
forming a barrier metal layer and a Cu-seed layer on the gate oxide; and
forming a Cu-metal layer on the Cu-seed layer.

15. The method of claim 13, wherein the etching of the insulating layer includes etching the insulating layer to expose the insulating an upper surface of the semiconductor substrate between the lightly doped drain regions.

16. The method of claim 13, wherein the forming of the lightly doped drain region includes:
forming a first photoresist pattern on the semiconductor substrate, and forming a first lightly doped drain region through an ion implantation process using the first photoresist pattern as an ion implantation mask;
removing the first photoresist pattern; and
forming a second photoresist pattern on the semiconductor substrate, and forming a second lightly doped drain region through an ion implantation process using the second photoresist pattern as an ion implantation mask.

17. The method of claim 16, wherein the etching of the insulating layer comprises:
forming a third photoresist pattern on the insulating layer;
performing a reactive ion etching process on the third photoresist pattern and the semiconductor substrate; and
removing a portion of the insulating layer through an etching process using the third photoresist pattern as an etch mask.

18. The method of claim 16, wherein the salicide is formed over the second lightly doped drain region.

19. The method of claim 16, wherein the first lightly doped drain region is a shallow lightly doped drain region, and the second lightly doped drain region is a deep lightly doped drain region.

20. The method of claim 13, wherein the oxide and the insulating layer are formed of tetra-ethyl-ortho-silicate.
